(19) United States
(12) Patent Application Publication
(10) Pub. No.: US 2025/0122607 A1
(43) Pub. Date: Apr. 17, 2025

(54) EVAPORATION DEVICE, EVAPORATION SYSTEM AND EVAPORATION METHOD

(71) Applicant: KunShan Go-Visionox Opto-Electronics Co., Ltd, Kunshan (CN)

(72) Inventors: Xuefeng ZHANG, Kunshan (CN); Shizhen FENG, Kunshan (CN); Jingjing ZHAO, Kunshan (CN); Mingxing LIU, Kunshan (CN)

(73) Assignee: KunShan Go-Visionox Opto-Electronics Co., Ltd, Kunshan (CN)

(21) Appl. No.: 19/001,867

(22) Filed: Dec. 26, 2024

Related U.S. Application Data
(63) Continuation of application No. PCT/CN2022/120631, filed on Sep. 22, 2022.

(30) Foreign Application Priority Data
Jul. 13, 2022 (CN) 202210820657.7

(51) Int. Cl. C23C 14/04; C23C 14/54

(52) U.S. Cl. CPC C23C 14/042; C23C 14/54

(57) ABSTRACT

An evaporation device, an evaporation system and an evaporation method. The evaporation device includes: a base body having an evaporation coating chamber, the evaporation coating chamber including a first evaporation coating region and a second evaporation coating region distributed sequentially in a first direction; a guide member located in the first evaporation coating region and the second evaporation coating region; an evaporation source assembly arranged at the guide member, the evaporation source assembly including a first evaporation source and a second evaporation source both the first evaporation source and the second evaporation source being movable back and forth in the first evaporation coating region and the second evaporation coating region, and both the first evaporation source and the second evaporation source being movable back and forth in a second direction relative to the guide member.

### CROSS REFERENCE TO RELATED APPLICATION

This application is a continuation of International Application No. PCT/CN2022/120631 filed on Sep. 22, 2022, which claims the priority benefits of Chinese Patent Application No. 202210820657.7 filed on Jul. 13, 2022 and entitled “Evaporation Device, Evaporation System and Evaporation Method”, both of which are incorporated herein by reference in their entireties.

### TECHNICAL FIELD

The invention relates to the field of evaporation coating technology, and in particular to an evaporation device, an evaporation system and an evaporation method.

### BACKGROUND

The conventional display devices are formed with films with evaporation technology. The existing evaporation system requires one chamber per film layer to be evaporation coated. Taking OLED devices as an example, there are typically 10-13 film layers currently, and then 10-13 evaporation devices are required to form an evaporation system. This makes the evaporation system has high cost, large space occupation and low capacity utilization.

### SUMMARY

The embodiments of the application provide an evaporation device, an evaporation system and an evaporation method. The evaporation device can meet the evaporation coating requirements of devices, while the evaporation system applied thereto has low cost, small space occupation and high capacity utilization.

In an aspect, the embodiments of the application provide an evaporation device including: a base body having an evaporation coating chamber, the evaporation coating chamber including a first evaporation coating region and a second evaporation coating region distributed sequentially in a first direction; a guide member located in the first evaporation coating region and the second evaporation coating region; an evaporation source assembly arranged at the guide member, the evaporation source assembly including a first evaporation source and a second evaporation source, the first evaporation source and the second evaporation source being movably connected to the guide member respectively, both the first evaporation source and the second evaporation source being movable back and forth in the first evaporation coating region and the second evaporation coating region, and both the first evaporation source and the second evaporation source being movable back and forth in a second direction relative to the guide member, the second direction intersecting with the first direction.

In another aspect, the embodiments of the application provide an evaporation system including the aforesaid evaporation device.

In yet another aspect, the embodiments of the application provide an evaporation method including:
a providing step of providing the aforesaid evaporation device and locating the first evaporation source in the first evaporation coating region and locating the second evaporation source in the second evaporation coating region;
a placing step of placing a first substrate to be evaporation coated in the first evaporation coating region and placing a second substrate to be evaporation coated in the second evaporation coating region;
an evaporation coating step of controlling the first evaporation source to move relative to the guide member and sequentially forming a first evaporation coating layer on the first substrate and the second substrate by evaporation coating, and controlling the second evaporation source to move relative to the guide member and sequentially forming a second evaporation coating layer on the first evaporation coating layer of the first substrate and the first evaporation coating layer of the second substrate.

According to yet another aspect of the embodiments of the application, the evaporation coating step including:
a preliminary evaporation coating step of controlling the first evaporation source to evaporation coat the first substrate to form a first evaporation coating layer;
a first position adjustment step of controlling the first evaporation source to enter the second evaporation coating region and controlling the second evaporation source to enter the first evaporation coating region;
a secondary evaporation coating step of controlling the first evaporation source to evaporation coat the second substrate to form a first evaporation coating layer and controlling the second evaporation source to form a second evaporation coating layer on the first evaporation coating layer formed on the first substrate by evaporation coating;
a first feeding step of taking out the first substrate formed with the first evaporation coating layer and the second evaporation coating layer by evaporation coating, and introducing a next first substrate to be evaporation coated;
a second position adjustment step of controlling the first evaporation source to enter the first evaporation coating region and controlling the second evaporation source to enter the second evaporation coating region;
a repeating evaporation coating step of controlling the first evaporation source to evaporation coat the reintroduced first substrate to be evaporation coated to form a first evaporation coating layer and controlling the second evaporation source to form a second evaporation coating layer on the first evaporation coating layer formed on the second substrate by evaporation coating;
a second feeding step of taking out the second substrate formed with the first evaporation coating layer and the second evaporation coating layer by evaporation coating, and introducing a next second substrate to be evaporation coated;
cyclically performing the first position adjustment step, the secondary evaporation coating step, the first feeding step, the second position adjustment step, the repeating evaporation coating step and the second feeding step, so as to form a first evaporation coating layer and a second evaporation coating layer on each of a plurality of first substrates and second substrates to be evaporation coated by the same evaporation device.

In the evaporation device, the evaporation system and the evaporation method provided according to the embodiments of the application, the evaporation device includes a base body, a guide member and an evaporation source assembly. An evaporation coating chamber of the base body includes a first evaporation coating region and a second evaporation coating region distributed sequentially in a first direction. The evaporation source assembly includes a first evaporation source and a second evaporation source located in the same evaporation coating chamber. The first evaporation source and the second evaporation source are movably connected to the guide member respectively. Both the first evaporation source and the second evaporation source are movable back and forth in the first evaporation coating region and the second evaporation coating region, and both the first evaporation source and the second evaporation source are movable back and forth in a second direction relative to the guide member, so that evaporation coating of two evaporation coating layers on two different substrates to be evaporation coated can be achieved in the same evaporation chamber. The evaporation device can meet the evaporation coating requirements of devices while reducing the amount of evaporation devices required for the evaporation system applied thereto. Taking OLED devices as an example, it requires only half of the amount of evaporation devices in prior art to meet the evaporation coating requirements for multi-film layers, with low cost, small space occupation and high capacity utilization.

### BRIEF DESCRIPTION OF THE DRAWINGS

The features, advantages and technical effects of the exemplary embodiments of the application will be described below with reference to the drawings.

FIG. 1 is a schematic structural view of an evaporation device according to an embodiment of the application;

FIG. 2 is a schematic structural view of an evaporation device according to another embodiment of the application with a first evaporation source in a first evaporation coating region and a second evaporation source in a second evaporation coating region;

FIG. 3 is a schematic view of an evaporation device according to another embodiment of the application with a first evaporation source and a second evaporation source operating in a second direction;

FIG. 4 is a schematic structural view of an evaporation device according to another embodiment of the application with a first evaporation source in a second evaporation coating region and a second evaporation source in a first evaporation coating region;

FIG. 5 is a schematic structural view of an evaporation device according to yet another embodiment of the application;

FIG. 6 is a schematic structural view of an evaporation device according to still another embodiment of the application;

FIG. 7 is a schematic structural view of an evaporation system according to an embodiment of the application;

FIG. 8 is a flow chart of an evaporation method according to an embodiment of the application;

FIGS. 9 to 14 are schematic structural views corresponding to the various steps of an evaporation method according to an embodiment of the application.

### DETAILED DESCRIPTION

The features in various aspects and exemplary embodiments of the application will be described in details below. In the following detailed description, numerous specific details are set forth in order to provide a thorough understanding of the present application. However, it is apparent to a person skilled in the art that the application may be implemented without some of these specific details. The following description of the embodiments is for the purpose of better understanding of the application through showing examples of the application. In the drawings and the following description, at least a portion of well-known structures and techniques are not shown in order to avoid unnecessarily obscuring the present application, and, for clarity, the dimensions of a portion of the structures may be exaggerated. In addition, the features, structures and characters described hereafter may be combined in any suitable way in one or more embodiments.

All the orientation terms present in the following description are the directions in the drawings, and do not limit a specific structure of the evaporation device, evaporation system and evaporation method of the application. In the description of the application, it is also noted that, except as otherwise stipulated or limited explicitly, the terms “mount”, “connect” shall be interpreted expansively, for example, it may be fixed connection, removable connection or integral connection; may be direct connection or indirect connection. For a person of ordinary skill in the art, the specific meaning of the above terms in the application can be interpreted depending on the specific situation.

The relevant display devices are formed with films with evaporation technology, and the existing evaporation device requires one chamber per film layer to be evaporation coated.

Taking OLED devices as an example, there are typically 10-13 film layers currently, and then 10-13 evaporation devices are required to form an evaporation system, and every two evaporation devices have to be equipped with one transport chamber, one transition chamber and a gas auxiliary chamber, so that the evaporation system composed of the evaporation devices has high cost, large space occupation and low capacity utilization.

In order to solve the aforesaid technical problem, the embodiments of the application provide an evaporation device, an evaporation system and an evaporation method. The evaporation coating is provided with two sets of evaporation sources simultaneously in one evaporation chamber, which means that evaporation coating of at least two film layers can be achieved by the same evaporation device, so that the evaporation system can save half of the evaporation devices and the corresponding transition chambers.

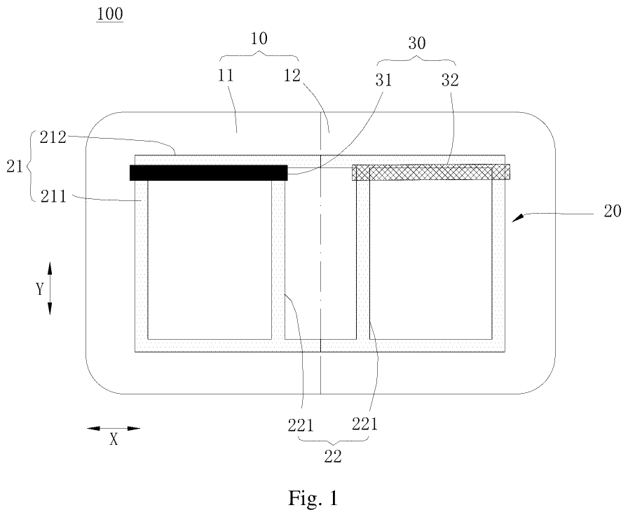

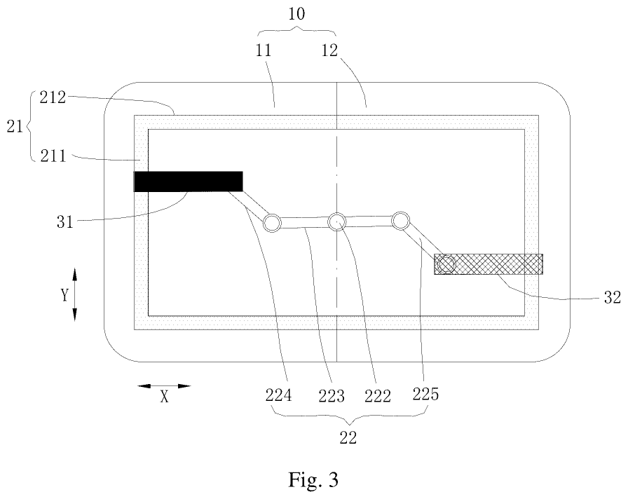

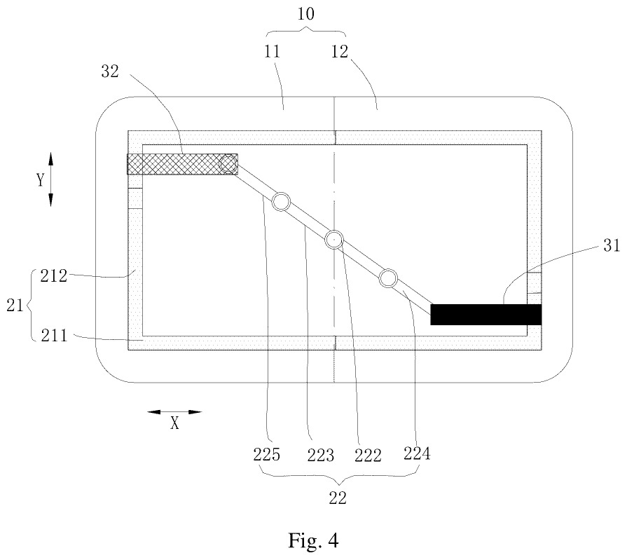

For better understanding of the application, the evaporation device, the evaporation system and the evaporation method according to the embodiments of the application will be described below in detail in combination with FIGS. 1 to 14.

Referring to FIG. 1, the embodiments of the application provide an evaporation device 100 including a base body 10, a guide member 20 and an evaporation source assembly 30. The base body 10 has an evaporation coating chamber, and the evaporation coating chamber includes a first evaporation coating region 11 and a second evaporation coating region 12 distributed sequentially in a first direction X. The guide member 20 is located in the first evaporation coating region 11 and the second evaporation coating region 12. The evaporation source assembly 30 is arranged at the guide member 20. The evaporation source assembly 30 includes a first evaporation source 31 and a second evaporation source 32. The first evaporation source 31 and the second evaporation source 32 are movably connected to the guide member 20 respectively. Both the first evaporation source 31 and the second evaporation source 32 are movable back and forth in the first evaporation coating region 11 and the second evaporation coating region 12, and both the first evaporation source 31 and the second evaporation source 32 are movable back and forth in a second direction Y relative to the guide member 20. The second direction Y intersects with the first direction X.

Optionally, the first evaporation coating region 11 and the second evaporation coating region 12 are two sequentially arranged regions located in the same evaporation coating chamber.

Optionally, “the guide member 20 is located in the first evaporation coating region 11 and the second evaporation coating region 12” can be understood to indicate that the guide member 20 may be partially located in the first evaporation coating region 11 and partially located in the second evaporation coating region 12.

Optionally, in an initial state, one of the first evaporation source 31 and the second evaporation source 32 may be located in the first evaporation coating region 11 and the other is located in the second evaporation coating region 12, and the first evaporation source 31 and the second evaporation source 32 may both be movably connected to the guide member 20 so as to move back and forth in the first evaporation coating region 11 and the second evaporation coating region 12 and be also able to move back and forth relative to the guide member 20 in the second direction Y within the same evaporation coating region.

Optionally, “the first evaporation source 31 and the second evaporation source 32 are movably connected to the guide member 20 respectively” can be understood to indicate that the positions of both the first evaporation source 31 and the second evaporation source 32 relative to the guide member 20 are adjustable, and the movable connection may include a connection type such as a sliding connection and a rolling connection that can adjust the positions of the first evaporation source 31 and the second evaporation source 32 relative to the guide member 20.

Optionally, the intersection angle between the first direction X and the second direction Y may be greater than 90° or may be less than 90°. Of course, the intersection angle between the first direction X and the second direction Y may also be equal to 90°.

Optionally, the first evaporation source 31 and the second evaporation source 32 may be point sources, or, of course, may be line sources, and may optionally be line sources.

In use of the evaporation device 100 provided by the embodiments of the application, in the same evaporation device 100 and in an initial state, it is possible to locate the first evaporation source 31 in the first evaporation coating region 11 and locate the second evaporation source 32 in the second evaporation coating region 12, and it is possible to place a first substrate to be evaporation coated in the first evaporation coating region 11 and place a second substrate to be evaporation coated in the second evaporation coating region 12. The first evaporation source 31 is controlled to move relative to the guide member 20 and a first evaporation coating layer is sequentially formed on the first substrate and the second substrate by evaporation coating, and the second evaporation source 32 is controlled to move relative to the guide member 20 and a second evaporation coating layer is sequentially formed on the first evaporation coating layer of the first substrate and the first evaporation coating layer of the second substrate.

That is, two different film layers can be evaporation coated on each substrate of two different substrates by the same evaporation device 100. Taking OLED devices as an example, since there are typically 10-13 film layers currently and 12 film layers are taken as an example, the evaporation method of the existing evaporation device 100 with one chamber per film results in that an existing evaporation system has to be composed of 12 evaporation devices. If the evaporation device 100 provided by the embodiments of the application is employed, when forming OLED devices by evaporation coating, only 6 evaporation devices 100 are required to accomplish evaporation coating of 10-13 film layers. This not only reduces the overall cost of the evaporation system, reduces the amount of evaporation devices 100, and reduces the occupied space to nearly half of the original space, but can also accomplish evaporation coating of two different substrates at once, resulting in high capacity utilization of the evaporation device 100 and the evaporation system applied thereto.

As an optional implementation, in the evaporation device 100 provided by the embodiments of the application, the evaporation source assembly 30 and the guide member 20 can switch between a first state and a second state. In the first state, the first evaporation source 31 is located in the first evaporation coating region 11 and the second evaporation source 32 is located in the second evaporation coating region 12. In the second state, the first evaporation source 31 moves to the second evaporation coating region 12 and the second evaporation source 32 moves to the first evaporation coating region 11.

Optionally, when the evaporation source assembly 30 and the guide member 20 are in any of the states, the first evaporation source 31 and the second evaporation source 32 are located in different evaporation regions.

By enabling the evaporation source assembly 30 and the guide member 20 to switch between the first state and the second state and locating, in different states, the first evaporation source 31 and the second evaporation source 32 in different evaporation regions, the evaporation device 100 provided by the embodiments of the application can avoid an interference between the first evaporation source 31 and the second evaporation source 32 during operation. At the same time, the aforesaid arrangement can also make it possible that, in use of the evaporation device 100, at least in some sections, the first evaporation source 31 and the second evaporation source 32 synchronously form different evaporation coating layers for different substrates to be evaporation coated. This not only ensures that evaporation coating of at least two different film layers of the same substrate is accomplished in the same evaporation chamber, but also ensures that evaporation coating of at least two different film layers of different substrates is accomplished in the same evaporation chamber, thereby improving capacity utilization.

As an optional implementation, in the evaporation device 100 provided by the embodiments of the application, the first evaporation source 31 and the second evaporation source 32 can move synchronously relative to the guide member 20.

That is, within the same time period, the first evaporation source 31 and the second evaporation source 32 may be moving relative to guide member 20 at the same time.

For example, it may be provided that, within the same time period, the first evaporation source 31 moves upwards in the second direction Y and the second evaporation source 32 moves downwards in the second direction Y. For another example, it may also be provided that, within the same time period, the first evaporation source 31 moves rightwards in the first direction X and the second evaporation source 32 moves leftwards in the first direction X.

Of course, in use of the evaporation device 100, the first evaporation source 31 and the second evaporation source 32 may move synchronously, or, of course, it is also possible that one is stationary while the other moves according to the evaporation coating requirements.

The evaporation device 100 provided by the embodiments of the application enables the first evaporation source 31 and the second evaporation source 32 to move synchronously relative to the guide member 20. If two substrates to be evaporation coated are placed in the same evaporation device 100, after one of the substrates has been evaporation coated with a first film layer by the first evaporation source 31, it is possible to synchronously move the first evaporation source 31 and the second evaporation source 32, causing the second evaporation source 32 to form a second film layer on the substrate already formed with the first film layer by evaporation coating while the first evaporation source 31 synchronously forms by evaporation coating a first film layer on the other substrate that has not been formed with a film layer yet. As a result, the production efficiency of the evaporation device 100 is effectively improved and the capacity utilization is improved.

As an optional implementation, in the evaporation device 100 provided by the embodiments of the application, the guide member 20 includes an edge guide portion 21 and a middle guide portion 22, the edge guide portion 21 is of a closed annular shape and located in the first evaporation coating region 11 and the second evaporation coating region 12, and the middle guide portion 22 is located in an annular cavity enclosed by the edge guide portion 21.

The first evaporation source 31 is connected to the edge guide portion 21 and the middle guide portion 22 and is at least movable along the edge guide portion 21. The second evaporation source 32 is connected to the edge guide portion 21 and the middle guide portion 22 and is at least movable along the edge guide portion 21.

Optionally, the edge guide portion 21 is of a closed annular shape, which may be a complete ring or, of course, may also be formed by connecting multiple guide rails.

Optionally, the edge guide portion 21 may be a polygonal ring and may optionally be a rectangular ring.

Optionally, the middle guide portion 22 is located in the annular cavity of the edge guide portion 21, and the middle guide portion may be connected to the edge guide portion 21, or, of course, may also be arranged to be spaced apart from the edge guide portion 21.

Optionally, the first evaporation source 31 and the second evaporation source 32 are movably connected to the edge guide portion 21 respectively, and the first evaporation source 31 and the second evaporation source 32 may be fixedly connected, or, of course, may also be movably connected, to the middle guide portion 22.

In the evaporation device 100 provided by the embodiments of the application, the guide member 20 includes the edge guide portion 21 and the middle guide portion 22, and the positional relationship between the edge guide portion 21 and the middle guide portion 22 and the connection coordination relationship between the first evaporation source 31 and the second evaporation source 32 are defined, so that the guide member 20 can meet the position adjustment requirements of the first evaporation source 31 and the second evaporation source 32 while enabling a simple overall structure of the guide member 20, which is conducive to molding with low cost.

As an optional implementation, in the evaporation device 100 provided by the embodiments of the application, the edge guide portion 21 is formed as a polygonal annular track.

Optionally, the edge guide portion 21 may be a quadrilateral annular track, and it may also be provided as a hexagonal, octagonal, or other annular track as required, which can be set according to the evaporation coating requirements.

In the evaporation device 100 provided by the embodiments of the application, by forming the edge guide portion 21 as a polygonal annular track, is conducive to the position adjustment of the first evaporation source 31 and the second evaporation source 32 in the first direction X and the second direction Y, thereby facilitating evaporation coating of at least two film layers on different substrates to be evaporation coated located in the same evaporation device 100.

As an optional implementation, in the evaporation device 100 provided by the embodiments of the application, the edge guide portion 21 includes at least one pair of first guide rails 211 and at least one pair of second guide rails 212. The at least one pair of first guide rails 211 are distributed in the first direction X and extend in the second direction Y, the at least one pair of second guide rails 212 are distributed in the second direction Y and extend in the first direction X, and the first guide rails 211 and the second guide rails 212 are alternately distributed and connected end to end.

Optionally, the amount of the first guide rails 211 may be two, or, of course, may also be four or six and the like, and may be optionally two.

Optionally, the amount of the second guide rails 212 may be two, or, of course, may also be four or six and the like, and may be optionally two.

Optionally, the at least one pair of first guide rails 211 and the at least one pair of second guide rails 212 may form a rectangular frame guide rail.

In the evaporation device 100 provided by the embodiments of the application, the edge guide portion 21 employs the aforesaid structural form, which, on the basis of meeting the requirements for stable adjustment of the positions of the first evaporation source 31 and the second evaporation source 32 in the first direction X and the second direction Y, can further simplify the structure of the edge guide portion 21.

As an optional implementation, in the evaporation device 100 provided by the embodiments of the application, the middle guide portion 22 includes two or more third guide rails 221 distributed in the first direction X. Each of the third guide rails 221 extends in the second direction Y and is connected to the edge guide portion 21. The first evaporation source 31 is movably connected to at least one of the third guide rails 221, and the second evaporation source 32 is movably connected to at least one of the third guide rails 221.

Optionally, the amount of third guide rails 221 may be two, or, of course, may also be more than two. Each of the third guide rails 221 extends in the second direction Y. It is possible to movably connect the first evaporation source 31 to one of the third guide rails 221, or to two or more of the third guide rails 221. It is possible to movably connect the second evaporation source 32 to one of the third guide rails 221, or to two or more of the third guide rails 221.

Optionally, one end in the second direction Y of the third guide rail 221 may be connected to one of the second guide rails 212 provided in pair, and the other end is connected to the other of the second guide rails 212 provided in pair.

Optionally, the third guide rail 221 is arranged spaced in the first direction X from and parallel to each of the at least one pair of first guide rails 211.

Optionally, the third guide rails 221 and the edge guide portion 21 may be of an integrated structure, or, of course, may also be of a split structure and connected in a way of welding or the like. Of course, in some other examples, each of the third guide rails and the edge guide portion 21 may be connected by contacting, for example, the two may abut with each other.

In the evaporation device 100 provided by the embodiments of the application, the middle guide portion 22 includes two or more third guide rails 221 distributed in the first direction X, and the coordination relationship between the first evaporation source 31, the second evaporation source 32 and the third guide rails 221, the edge guide portion 21 is defined, which is conducive to the movement requirements of the first evaporation source 31 and the second evaporation source 32 in the first direction X and the second direction Y, thereby enabling the movement in the second direction Y in one evaporation region while enabling switching between different evaporation regions in the first direction X, ensuring the evaporation coating requirements for two different film layers of each of the two different substrates.

It can be understood that the form of the middle guide portion 22 including two or more third guide rails 221 is only an optional embodiment, but it is not limited to the above form.

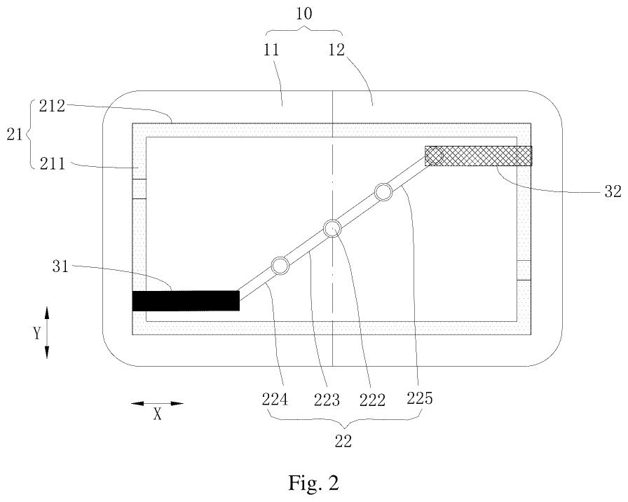

Referring to FIGS. 2 to 4, in some embodiments, it is also possible that the middle guide portion 22 includes a pivot shaft 222, a main connection shaft 223, a first connection arm 224 and a second connection arm 225. The main connection shaft 223 is rotatably connected to the pivot shaft 222 and is rotatable with the pivot shaft 222 as a rotation center. One end of the main connection shaft 223 is rotatably connected to the first connection arm 224 and the other end is rotatably connected to the second connection arm 225. The first evaporation source 31 is arranged at the first connection arm 224 and slidably connected to the edge guide portion 21. The second evaporation source 32 is arranged at the second connection arm 225 and slidably connected to the edge guide portion 21.

Optionally, the pivot shaft 222 and the main connection shaft 223 may be arranged to intersect with each other, optionally arranged perpendicular to each other, and the main connection shaft 223 can rotate with the pivot shaft 222 as the rotation center.

Optionally, it is possible that the main connection shaft 223 is rotatably connected at a center position in its own length direction to the pivot shaft 222.

Optionally, the first connection arm 224 has a predetermined length, and one end of the first connection arm 224 in its own length direction is rotatably connected (may be connected by a pivot shaft) to one end of the main connection shaft 223. Correspondingly, the second connection arm 225 has a predetermined length, and one end of the second connection arm 225 in its own length direction is rotatably connected (may be connected by a pivot shaft) to the other end of the main connection shaft 223.

Optionally, one end of the first evaporation source 31 may be slidably fit with the edge guide portion 21 and the other end may be fixedly connected to one end of the first connection arm 224 away from the main connection shaft 223. Correspondingly, one end of the second evaporation source 32 may be slidably connected to the edge guide portion 21 and the other end is fixedly connected to the other end of the second connection arm 225 away from the main connection shaft 223.

As shown in FIGS. 2 to 4, in the evaporation device 100 provided by the embodiments of the application, the guide portion 22 employs the above structural form. When it is required to adjust the positions of the first evaporation source 31 and the second evaporation source 32, the main connection shaft 223 may be driven to rotate with the pivot shaft 222 as the rotation center, and the rotation of the main connection shaft 223 will drive the first connection arm 224 and the second connection arm 225 to move, so as to drive the first evaporation source 31 and the second evaporation source 32 to move along the edge guide portion 21. When the main connection shaft 223 rotates for an angle less than or equal to 180° with the pivot shaft 222 as the rotation center, the first evaporation source 31 and the second evaporation source 32 can move relative to the edge guide portion 21 in the second direction Y in the first evaporation coating region 11 or the second evaporation coating region 12. When the main connection shaft 223 rotates for an angle exceeding 180° with the pivot shaft 222 as the rotation center, the first evaporation source 31 and the second evaporation source 32 can be caused to move in the first direction X in the first evaporation coating region 11 and the second evaporation coating region 12. It is also possible to meet the position adjustment requirements of the first evaporation source 31 and the second evaporation source 32.

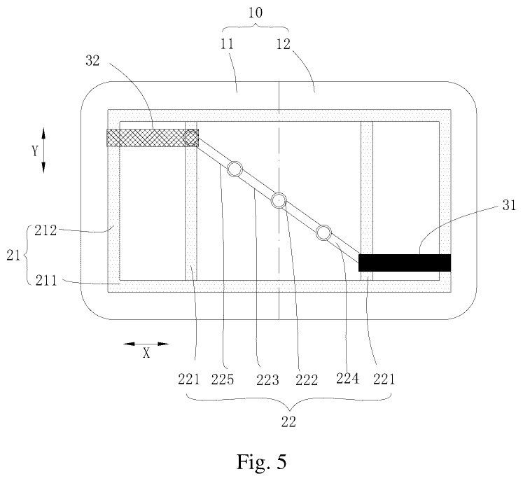

Referring to FIG. 5, in some embodiments, in the evaporation device 100 provided by the embodiments of the application, the middle guide portion 22 may include two or more third guide rails 221, a pivot shaft 222, a main connection shaft 223, a first connection arm 224 and a second connection arm 225 at the same time.

Two or more third guide rails 221 are distributed in the first direction X. Each of the third guide rails 221 extends in the second direction Y and is connected to the edge guide portion 21. The first evaporation source 31 is movably connected to at least one of the third guide rails 221, and the second evaporation source 32 is movably connected to at least one of the third guide rails 221. For ease of understanding, take the middle guide portion 22 including two third guide rails 221 as an example for illustration. The pivot shaft 222 may be located between two adjacent third guide rails 221, the main connection shaft 223 is rotatably connected to the pivot shaft 222 and is rotatable with the pivot shaft 222 as the rotation center. One end of the main connection shaft 223 is rotatably connected to the first connection arm 224 and the other end is rotatably connected to the second connection arm 225. The first evaporation source 31 is arranged at the first connection arm and slidably connected to the edge guide portion 21 and one of the third guide rails 221. The second evaporation source 32 is arranged at the second connection arm 225 and slidably connected to the edge guide portion 21 and another of the third guide rail 221.

In the evaporation device provided by the embodiments of the application, the middle guide portion includes the third guide rails 221, the pivot shaft 222, the main connection shaft 223, the first connection arm 224 and the second connection arm 225 at the same time. When it is required to adjust the positions of the first evaporation source 31 and the second evaporation source 32, the main connection shaft 223 may be driven to rotate with the pivot shaft 222 as the rotation center, and the rotation of the main connection shaft 223 will drive the first connection arm 224 and the second connection arm 225 to move, so as to drive the first evaporation source 31 and the second evaporation source 32 to move.

When the main connection shaft 223 rotates for an angle less than or equal to 180° with the pivot shaft 222 as the rotation center, the first evaporation source 31 can move relative to the edge guide portion 21 and one of the third guide rails 221 in the second direction Y in the first evaporation coating region 11 or the second evaporation coating region 12, and at the same time, the second evaporation source 32 can move relative to the edge guide portion 21 and one of the third guide rails 221 in the second direction Y in the first evaporation coating region 11 or the second evaporation coating region 12.

When the main connection shaft 223 rotates for an angle exceeding 180° with the pivot shaft 222 as the rotation center, it can cause the first evaporation source 31 and the second evaporation source 32 to move in the first direction X and relative to the edge guide portion 21 in the first evaporation coating region 11 and the second evaporation coating region 12. It is also possible to meet the position adjustment requirements of the first evaporation source 31 and the second evaporation source 32.

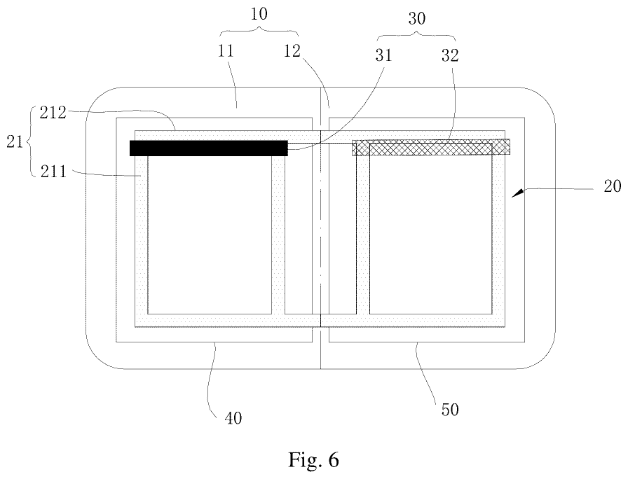

Referring to FIG. 6, as an optional implementation, the evaporation device 100 provided by the embodiments of the application further includes a first carrier plate 40 and a second carrier plate 50 for carrying a substrate to be evaporation coated. The first carrier plate 40 is arranged in the first evaporation coating region 11, and the second carrier plate 50 is arranged in the second evaporation coating region 12.

Optionally, the shapes of the first carrier plate 40 and of the second carrier plate 50 may be the same, and in the first direction X, the first carrier plate 40 and the second carrier plate 50 may be arranged opposite to each other.

Optionally, both the first carrier plate 40 and the second carrier plate 50 are used to carry the substrate to be evaporation coated. When the evaporation device 100 is in operation, the first carrier plate 40 may be used to carry a first substrate to be evaporation coated, and the second carrier plate 50 may be used to carry a second substrate to be evaporation coated.

Optionally, the surfaces of the first carrier plate 40 and the second carrier plate 50 arranged towards the evaporator source assembly 30 may be flush with each other.

By providing the first carrier plate 40 and the second carrier plate 50, the evaporation device 100 provided by the embodiments of the application can be used to synchronously support at least two substrates to be evaporation coated, so that the flatness of the substrates to be evaporation coated can be ensured while positioning of the substrates to be evaporation coated can also be achieved by the positions where the first carrier plate 40 and the second carrier plate 50 are located, so as to ensure the evaporation coating effect.

As an optional implementation, the evaporation device 100 provided by the embodiments of the application further includes a separation plate (not shown). The separation plate is arranged at the base body 10 and at least partially separates the first evaporation coating region 11 and the second evaporation coating region 12.

Optionally, an avoidance space is provided on the separation plate capable of providing avoidance for the movement of the first evaporation source 31 and the second evaporation source 32 in the first direction X and the second direction Y.

By providing the separation plate, the evaporation device 100 provided by the embodiments of the application can block a material sprayed from the first evaporation source 31 and a material sprayed from the second evaporation source 32 to a certain extent, reducing crosstalk between the two and ensuring the performance of the formed film layers.

As an optional implementation, the evaporation device 100 provided by the embodiments of the application further includes a collector and a controller. The collector is configured to collect temperature information in the evaporation coating chamber, and the controller is configured to determine a mesh compensation amount of a mask according to a difference between the temperature information and a preset temperature threshold.

Optionally, the collector may include a temperature sensor.

Optionally, there may be a mapping table between the difference between the temperature information and the preset temperature threshold and the mesh compensation amount. It is possible to obtain a corresponding mesh compensation amount by searching for the difference between the temperature information and the preset temperature threshold and then mesh the mask. The mapping table between the difference between the temperature information and the preset temperature threshold and the mesh compensation amount has formed an industry standard in the field of evaporation coating, in particular panel evaporation coating, and is relatively universal, which will not be further repeated in the application.

Since two evaporation coating regions and two evaporation sources are provided in one evaporation coating chamber at the same time, the temperature inside the evaporation coating chamber will be too high. After the temperature rises, if the mask is still meshed according to the meshing regulation in the unraised temperature, the meshing accuracy of the mask will be reduced. By providing the collector, the evaporation device 100 provided by the embodiments of the application can collect temperature information of the first evaporation coating region 11 and the second evaporation coating region 12 in the evaporation coating chamber. Due to different temperature requirements for meshing of a mask, the mesh compensation amount for a mask is determined according to the difference between the temperature information and the preset temperature to ensure meshing accuracy, avoid temperature rise affecting meshing accuracy, and optimize the evaporation coating effect.

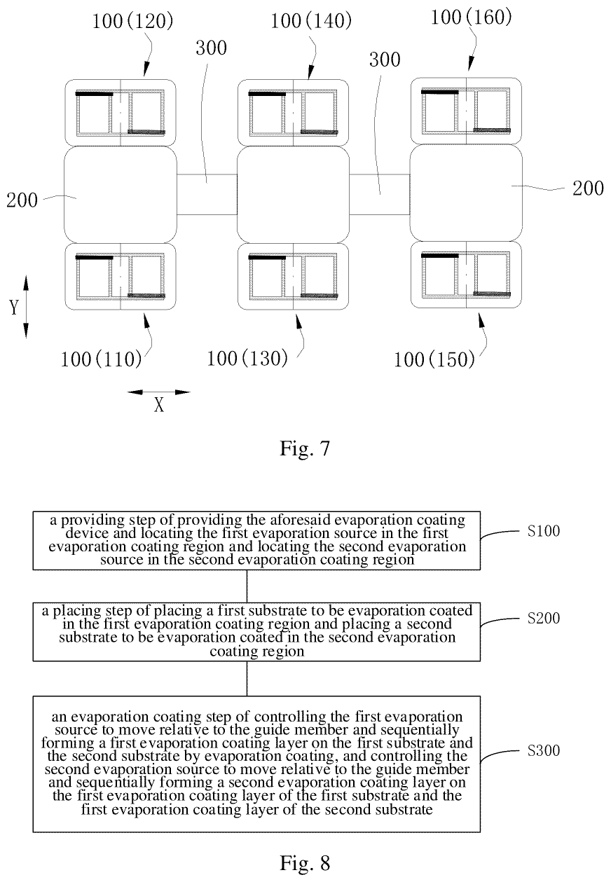

Referring to FIG. 7, in another aspect, the embodiments of the application also provide an evaporation system, including the evaporation device 100 provided by the aforementioned various embodiments.

Optionally, the amount of the evaporation devices 100 included in the evaporation system may be two, three or more, which may be determined according to the required amount of film layers on the evaporation coating substrate. Taking an OLED device as an example, provided that the OLED device is required to be formed with 12 film layers by evaporation coating, it is possible that the evaporation system includes six evaporation devices 100, each two evaporation devices 100 form a group and are distributed in the second direction Y, three groups of evaporation devices 100 are distributed in the first direction X, two evaporation devices 100 in the same group are in communication via one transport chamber 200, and a transition chamber 300 is connected between the transport chambers 200 of two adjacent evaporation devices 100.

For better understanding, it will be exemplified below taking six evaporation devices 100 as an example, namely a first evaporation device 110, a second evaporation device 120, a third evaporation device 130, a fourth evaporation device 140, a fifth evaporation device 150 and a sixth evaporation device 160.

Two substrates to be evaporation coated, namely a first substrate and a second substrate, may be placed in the first evaporation device 110. In the first evaporation device 110, a first film layer may be formed on the first substrate and the second substrate respectively by controlling the movement of the first evaporation source 31, and a second film layer may be formed on the first film layer formed on the first substrate and the second substrate respectively by controlling the movement of the second evaporation source 32.

The first substrate and the second substrate formed with the first film layers and the second film layer are sequentially transported to the second evaporation device 120 via the transport chamber 200. A third film layer and a fourth film layer are formed on the second film layer of the first substrate and the second substrate respectively by the second evaporation device 120. The first substrate and the second substrate formed with the the fourth film layer are transported to the third evaporation device 130 via the transition chamber 300 between two groups of evaporation devices 100 and are formed a fifth film layer and a sixth film layer, and so on in a similar fashion, until a eleventh film layer and a twelfth film layer are formed in the sixth evaporation device 160 to meet the evaporation coating requirement of the OLED devices.

Since the evaporation system provided by the embodiments of the application includes the evaporation devices 100 provided by the aforesaid various embodiments, by enabling the same evaporation device 100 to evaporation coat two different film layers on each substrate of two different substrates, only six evaporation devices 100 are required to accomplish evaporation coating of 12 film layers in evaporation coating of the OLED devices. This not only reduces the overall cost of the evaporation system, reduces the amount of the evaporation devices 100 and reduces the occupied space to nearly half of the original space, but also accomplishes evaporation coating of two different substrates at once, resulting in a high capacity utilization of the evaporation devices 100 and the evaporation system applied thereto.

Referring to FIGS. 8 to 14, in yet another aspect, the embodiments of the application also provide an evaporation method including:
S100, a providing step of providing the evaporation device 100 of the various embodiments described above and locating the first evaporation source 31 in the first evaporation coating region 11 and locating the second evaporation source 32 in the second evaporation coating region 12;
S200, a placing step of placing a first substrate to be evaporation coated in the first evaporation coating region 11 and placing a second substrate to be evaporation coated in the second evaporation coating region 12;
S300, an evaporation coating step of controlling the first evaporation source 31 to move relative to the guide member 20 and sequentially forming a first evaporation coating layer on the first substrate and the second substrate by evaporation coating, and controlling the second evaporation source 32 to move relative to the guide member 20 and sequentially forming a second evaporation coating layer on the first evaporation coating layer of the first substrate and the first evaporation coating layer of the second substrate.

Optionally, in the step S100, the amount of evaporation device 100 as provided may be one, or, of course, may also be two or more. Optionally, the first evaporation source 31 and the second evaporation source 32 in the same evaporation device 100 may be located on the same side of the guide member 20 in the second direction Y, or, of course, may also be located on different sides of the guide member 20, where the two may be arranged diagonally.

Optionally, in the step S200, when the evaporation device 100 includes a first carrier plate 40 and a second carrier plate 50, the first substrate to be evaporation coated may be placed on the first carrier plate 40 and the second substrate to be evaporation coated may be placed on the second carrier plate 50.

Optionally, in the step S300, it is possible to control the first evaporation source 31 to at first move relative to the guide member 20 in the second direction Y and form a first evaporation coating layer on the first substrate, then control the first evaporation source 31 to move to the second evaporation coating region 12 and control the second evaporation source 32 to move to the first evaporation coating region 11, then control the first evaporation source 31 to move relative to the guide member 20 in the second direction Y and form a first evaporation coating layer on the second substrate and control the second evaporation source 32 to move relative to the guide member 20 in the second direction Y and form a second evaporation coating layer on the first evaporation coating layer of the first substrate, and then use the second evaporation source 32 to form a second evaporation coating layer on the first evaporation coating layer of the second substrate.

The evaporation method provided by the embodiments of the application employs the evaporation device 100 provided by the above embodiments, with a high evaporation coating efficiency and capacity utilization by enabling the same evaporation device 100 to evaporation coat two different film layers on each substrate of two different substrates respectively.

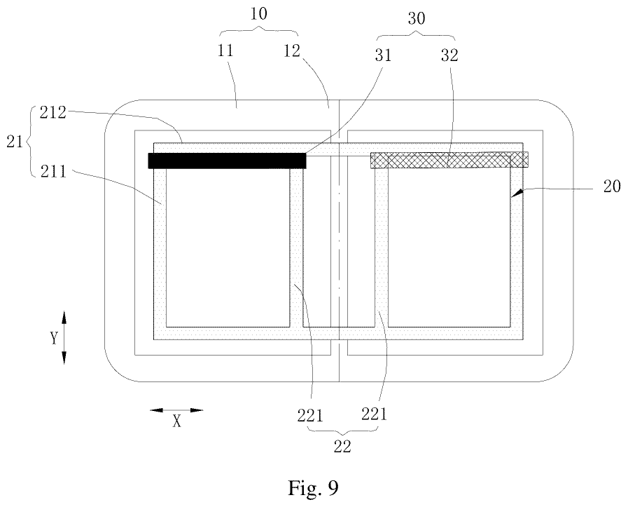

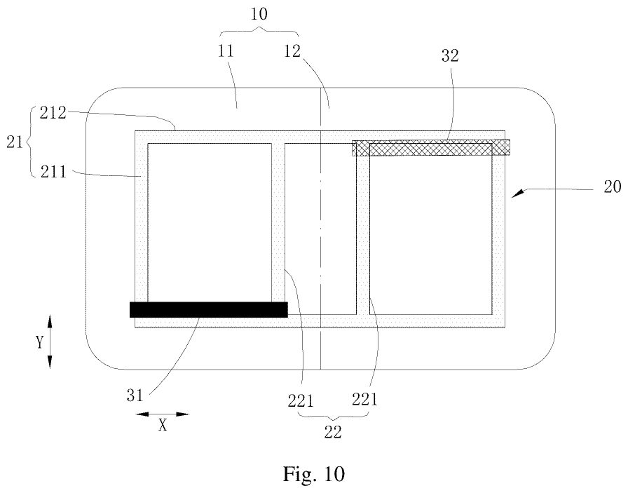

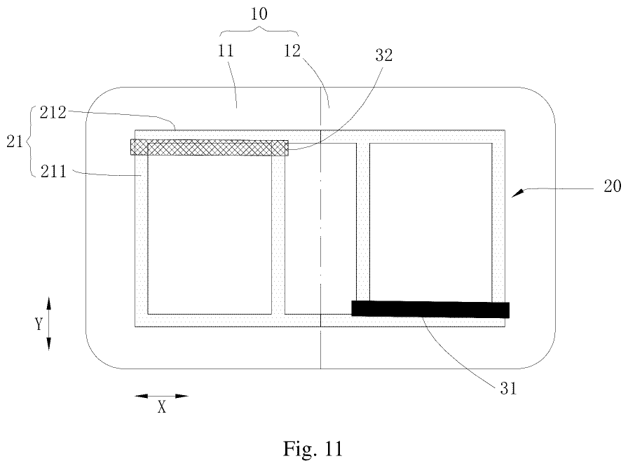

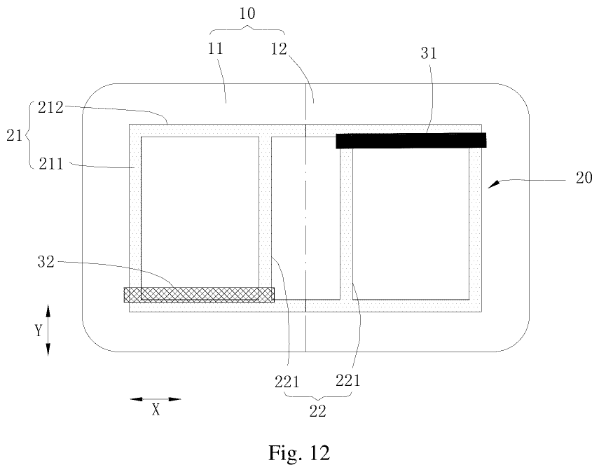

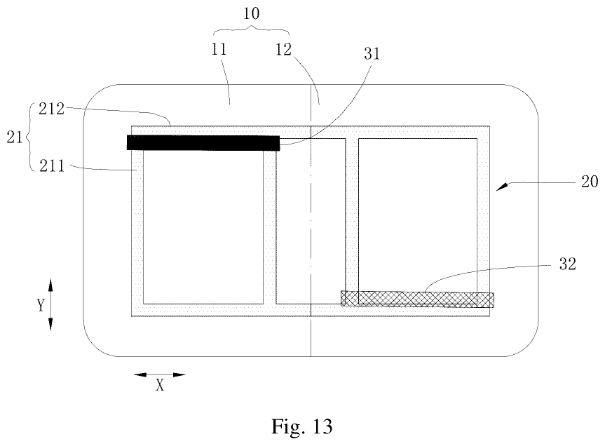

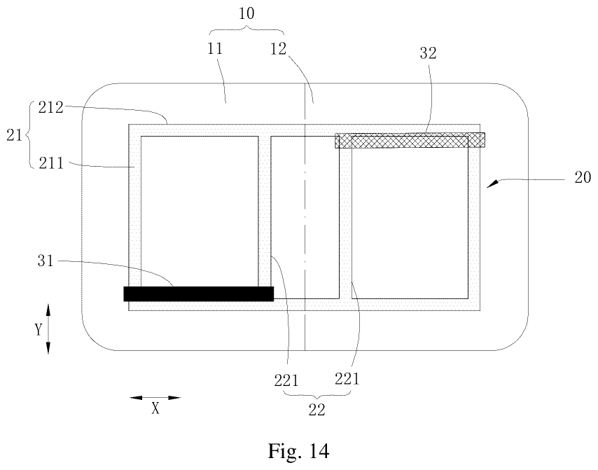

As an optional implementation, in the evaporation method provided by the embodiments of the application, the evaporation coating step includes:
a preliminary evaporation coating step of controlling the first evaporation source 31 to evaporation coat the first substrate to form a first evaporation coating layer, as shown in FIGS. 9 and 10;
a first position adjustment step of controlling the first evaporation source 31 to enter the second evaporation coating region 12 and controlling the second evaporation source 32 to enter the first evaporation coating region 11, as shown in FIG. 11;
a secondary evaporation coating step of controlling the first evaporation source 31 to evaporation coat the second substrate to form a first evaporation coating layer and controlling the second evaporation source 32 to form a second evaporation coating layer on the first evaporation coating layer formed on the first substrate by evaporation coating, as shown in FIG. 12;
a first feeding step of taking out the first substrate formed with the first evaporation coating layer and the second evaporation coating layer by evaporation coating, and introducing a next first substrate to be evaporation coated;
a second position adjustment step of controlling the first evaporation source 31 to enter the first evaporation coating region 11 and controlling the second evaporation source 32 to enter the second evaporation coating region 12, as shown in FIG. 13;
a repeating evaporation coating step of controlling the first evaporation source 31 to evaporation coat the reintroduced first substrate to be evaporation coated to form a first evaporation coating layer and controlling the second evaporation source 32 to form a second evaporation coating layer on the first evaporation coating layer formed on the second substrate by evaporation coating, as shown in FIG. 14;
a second feeding step of taking out the second substrate formed with the first evaporation coating layer and the second evaporation coating layer by evaporation coating, and introducing a next second substrate to be evaporation coated;
cyclically performing the first position adjustment step, the secondary evaporation coating step, the first feeding step, the second position adjustment step, the repeating evaporation coating step and the second feeding step, so as to form a first evaporation coating layer and a second evaporation coating layer on each of a plurality of first substrates and second substrates to be evaporation coated by the same evaporation device 100.

Optionally, in the preliminary evaporation coating step, it is possible to control the first evaporation source 31 to move in the second direction Y, scan the first substrate and evaporation coat the first substrate to form a first evaporation coating layer.

Optionally, in the first position adjustment step, the first evaporation source 31 and the second evaporation source 32 may be controlled to move oppositely in the first direction X, so that the first evaporation source 31 enters the second evaporation coating region 12, and the second evaporation source 32 is controlled to enter the first evaporation coating region 11. It is possible to synchronously control the first evaporation source 31 and the second evaporation source 32 to move into the corresponding evaporation regions. Of course, it is also possible to control the first evaporation source 31 and the second evaporation source 32 to move into the corresponding evaporation coating regions in steps, which may be selected as synchronous control.

Optionally, in the secondary evaporation coating step, the first evaporation source 31 and the second evaporation source 32 may be controlled to move relative to the guide member 20 in the second direction Y respectively, so as to form a first evaporation coating layer on the second substrate by the first evaporation source 31 and form a second evaporation coating layer on the first substrate by the second evaporation source 32. It is possible to control the first evaporation source 31 to evaporation coat the second substrate to form the first evaporation coating layer and control the second evaporation source 32 to form a second evaporation coating layer on the first evaporation coating layer formed on the first substrate by evaporation coating synchronously. Of course, it is also possible to control the first evaporation source 31 to evaporation coat the second substrate to form a first evaporation coating layer and control the second evaporation source 32 to form a second evaporation coating layer on the first evaporation coating layer formed on the first substrate by evaporation coating in steps, which may be selected as synchronous control.

Optionally, the materials sprayed by the first evaporation source 31 and the second evaporation source 32 in the same evaporation device 100 have similar properties and functions, and are free of pollution.

Optionally, in the first feeding step, the first substrate formed with the first evaporation coating layer and the second evaporation coating layer by evaporation coating, which is taken out, may enter a next evaporation device 100 to be formed with a third evaporation coating layer and a fourth evaporation coating layer and the like by evaporation coating. The introduced next first substrate to be evaporation coated may be arranged opposite to the second substrate already formed with the first evaporation coating layer in the first direction X. Optionally, taking out the first substrate already formed with the first evaporation coating layer and the second evaporation coating layer by evaporation coating and introducing the next first substrate to be evaporation coated may be performed simultaneously. Of course, it is also possible to take out the first substrate already formed with the first evaporation coating layer and the second evaporation coating layer by evaporation coating at first, and then introduce the next first substrate to be evaporation coated.

Optionally, in the second position adjustment step, the first evaporation source 31 and the second evaporation source 32 may be controlled to move oppositely in the first direction X, so that the first evaporation source 31 returns to the first evaporation coating region 11, and the second evaporation source 32 is controlled to return to the second evaporation coating region 12. It is possible to synchronously control the first evaporation source 31 to enter the first evaporation coating region 11 and control the second evaporation source 32 to enter the second evaporation coating region 12. Of course, it is also possible to control the first evaporation source 31 to enter the first evaporation coating region 11 and control the second evaporation source 32 to enter the second evaporation coating region 12 in steps, which may be selected as synchronous control.

Optionally, in the repeating evaporation coating step, the first evaporation source 31 and the second evaporation source 32 are controlled to move relative to the guide member 20 in the second direction Y respectively, so as to use the first evaporation source 31 to evaporation coat the reintroduced first substrate to be evaporation coated to form a first evaporation coating layer and use the second evaporation source 32 to form a second evaporation coating layer on the first evaporation coating layer formed on the second substrate by evaporation coating. It is possible to synchronously control the first evaporation source 31 to evaporation coat the reintroduced first substrate to be evaporation coated to form a first evaporation coating layer and control the second evaporation source 32 to form a second evaporation coating layer on the first evaporation coating layer formed on the second substrate by evaporation coating. Of course, it is also possible to control the first evaporation source 31 to evaporation coat the reintroduced first substrate to be evaporation coated to form a first evaporation coating layer and control the second evaporation source 32 to form a second evaporation coating layer on the first evaporation coating layer formed on the second substrate by evaporation coating in steps, which may be selected as synchronous control.

Optionally, in the second feeding step, the second substrate already formed with the first evaporation coating layer and the second evaporation coating layer by evaporation coating, which is taken out, may enter a next evaporation device 100 to be formed with a third evaporation coating layer and a fourth evaporation coating layer and the like by evaporation coating. The introduced next second substrate to be evaporation coated may be arranged opposite to the first substrate already formed with the first evaporation coating layer in the first direction X. It is possible to take out the second substrate already formed with the first evaporation coating layer and the second evaporation coating layer by evaporation coating and introduce the next second substrate to be evaporation coated simultaneously. Of course, it is also possible to take out the second substrate already formed with the first evaporation coating layer and the second evaporation coating layer by evaporation coating at first, and then introduce the next second substrate to be evaporation coated.

Optionally, the first position adjustment step, the secondary evaporation coating step, the first feeding step, the second position adjustment step, the repeating evaporation coating step and the second feeding step are cyclically performed, until each of all the first substrates and second substrates to be evaporation coated is formed with a first evaporation coating layer and a second evaporation coating layer.

In the evaporation method provided by the embodiments of the application, the evaporation coating steps employ the above operation process, facilitating using the same evaporation device 100 to evaporation coat two different film layers on each substrate of two different substrates respectively, saving five alignment and separation processes for ten film layers. Provided that a beat time is 240 seconds per piece, it is estimated to be shortened to 180 seconds, with a 25% increase in capacity utilization and a higher evaporation coating efficiency and capacity utilization.

Although the application has been described in reference to preferred embodiments, it is possible to make various improvements of it and substitute components therein with equivalents without departing from the scope of the application. In particular, the various technical features mentioned in various embodiments can be combined in any way. The application is not limited to the specific embodiments disclosed herein, but includes all the technical solutions which fall into the scope of the claims.

What is claimed is:

1. An evaporation device comprising:
a base body having an evaporation coating chamber, the evaporation coating chamber comprising a first evaporation coating region and a second evaporation coating region distributed sequentially in a first direction;
a guide member located in the first evaporation coating region and the second evaporation coating region;
an evaporation source assembly arranged at the guide member, the evaporation source assembly comprising a first evaporation source and a second evaporation source, the first evaporation source and the second evaporation source being movably connected to the guide member respectively, both the first evaporation source and the second evaporation source being movable back and forth in the first evaporation coating region and the second evaporation coating region, and both the first evaporation source and the second evaporation source being movable back and forth in a second direction relative to the guide member, the second direction intersecting with the first direction.

2. The evaporation device according to claim 1, wherein the evaporation source assembly and the guide member are switchable between a first state and a second state;
in the first state, the first evaporation source is located in the first evaporation coating region and the second evaporation source is located in the second evaporation coating region;
in the second state, the first evaporation source moves to the second evaporation coating region and the second evaporation source moves to the first evaporation coating region.

3. The evaporation device according to claim 2, wherein the first evaporation source and the second evaporation source are movable synchronously with respect to the guide member.

4. The evaporation device according to claim 1, wherein the guide member comprises an edge guide portion and a middle guide portion, the edge guide portion is of a closed annular shape and located in the first evaporation coating region and the second evaporation coating region, and the middle guide portion is located in an annular cavity enclosed by the edge guide portion;
the first evaporation source is connected to the edge guide portion and the middle guide portion and is at least movable along the edge guide portion, and the second evaporation source is connected to the edge guide portion and the middle guide portion and is at least movable along the edge guide portion.

5. The evaporation device according to claim 4, wherein the edge guide portion is formed as a polygonal annular track.

6. The evaporation device according to claim 5, wherein the edge guide portion comprises at least one pair of first guide rails and at least one pair of second guide rails, the at least one pair of first guide rails are distributed in the first direction and extend in the second direction, the at least one pair of second guide rails are distributed in the second direction and extend in the first direction, and the at least one pair of first guide rails and the at least one pair of second guide rails are alternately arranged and connected end to end.

7. The evaporation device according to claim 6, wherein the at least one pair of first guide rails and the at least one pair of second guide rails form a rectangular frame guide rail.

8. The evaporation device according to claim 6, wherein the middle guide portion comprises two or more third guide rails distributed in the first direction, each of the third guide rails extends in the second direction and is connected to the edge guide portion, the first evaporation source is movably connected to at least one of the third guide rails, and the second evaporation source is movably connected to at least one of the third guide rails.

9. The evaporation device according to claim 8, wherein one end in the second direction of the third guide rail is connected to one of the second guide rails provided in pair, and the other end in the second direction of the third guide rail is connected to the other of the second guide rails provided in pair.

10. The evaporation device according to claim 8, wherein the third guide rail is arranged spaced in the first direction from and parallel to each of the at least one pair of first guide rails.

11. The evaporation device according to claim 4, wherein the middle guide portion comprises a pivot shaft, a main connection shaft, a first connection arm and a second connection arm, the main connection shaft is rotatably connected to the pivot shaft and is rotatable with the pivot shaft as a rotation center, one end of the main connection shaft is rotatably connected to the first connection arm and the other end is rotatably connected to the second connection arm, the first evaporation source is arranged at the first connection arm and slidably connected to the edge guide portion, and the second evaporation source is arranged at the second connection arm and slidably connected to the edge guide portion.

12. The evaporation device according to claim 11, wherein the main connection shaft is rotatably connected at a center position in its own length direction to the pivot shaft.

13. The evaporation device according to claim 11, wherein one end of the first evaporation source is slidably fit with the edge guide portion and the other end is fixedly connected to an end of the first connection arm away from the main connection shaft, and one end of the second evaporation source is slidably connected to the edge guide portion and the other end is fixedly connected to an end of the second connection arm away from the main connection shaft.

14. The evaporation device according to claim 4, wherein the middle guide portion comprises two or more third guide rails, a pivot shaft, a main connection shaft, a first connection arm and a second connection arm, the two or more third guide rails are distributed in the first direction, each of the third guide rails extends in the second direction and is connected to the edge guide portion, the pivot shaft is located between adjacent two of the three third guide rails, the main connection shaft is rotatably connected to the pivot shaft and is rotatable with the pivot shaft as a rotation center, one end of the main connection shaft is rotatably connected to the first connection arm and the other end is rotatably connected to the second connection arm, the first evaporation source is arranged at the first connection arm and slidably connected to the edge guide portion and one of the third guide rails, and the second evaporation source is arranged at the second connection arm and slidably connected to the edge guide portion and another of the third guide rails.

15. The evaporation device according to claim 1, wherein the evaporation device further comprises a first carrier plate and a second carrier plate for carrying a substrate to be evaporation coated, the first carrier plate is arranged in the first evaporation coating region, and the second carrier plate is arranged in the second evaporation coating region.

16. The evaporation device according to claim 1, wherein the evaporation device further comprises a separation plate, and the separation plate is arranged at the base body and at least partially separates the first evaporation coating region and the second evaporation coating region.

17. The evaporation device according to claim 1, wherein the evaporation device further comprises a collector and a controller, the collector is configured to collect temperature information in the evaporation coating chamber, and the controller is configured to determine a mesh compensation amount of a mask according to a difference between the temperature information and a preset temperature threshold.

18. An evaporation system, wherein the evaporation system comprises the evaporation device according to claim 1.

19. An evaporation method, wherein the evaporation method comprising:
a providing step of providing the evaporation device according to claim 1 and locating the first evaporation source in the first evaporation coating region and locating the second evaporation source in the second evaporation coating region;
a placing step of placing a first substrate to be evaporation coated in the first evaporation coating region and placing a second substrate to be evaporation coated in the second evaporation coating region;
an evaporation coating step of controlling the first evaporation source to move relative to the guide member and sequentially forming a first evaporation coating layer on the first substrate and the second substrate by evaporation coating, and controlling the second evaporation source to move relative to the guide member and sequentially forming a second evaporation coating layer on the first evaporation coating layer of the first substrate and the first evaporation coating layer of the second substrate.

20. The evaporation method according to claim 19, wherein the evaporation coating step comprises:
a preliminary evaporation coating step of controlling the first evaporation source to evaporation coat the first substrate to form a first evaporation coating layer;
a first position adjustment step of controlling the first evaporation source to enter the second evaporation coating region and controlling the second evaporation source to enter the first evaporation coating region;
a secondary evaporation coating step of controlling the first evaporation source to evaporation coat the second substrate to form a first evaporation coating layer and controlling the second evaporation source to form a second evaporation coating layer on the first evaporation coating layer formed on the first substrate by evaporation coating;
a first feeding step of taking out the first substrate formed with the first evaporation coating layer and the second evaporation coating layer by evaporation coating, and introducing a next first substrate to be evaporation coated;
a second position adjustment step of controlling the first evaporation source to enter the first evaporation coating region and controlling the second evaporation source to enter the second evaporation coating region;
a repeating evaporation coating step of controlling the first evaporation source to evaporation coat the reintroduced first substrate to be evaporation coated to form a first evaporation coating layer and controlling the second evaporation source to form a second evaporation coating layer on the first evaporation coating layer formed on the second substrate by evaporation coating;
a second feeding step of taking out the second substrate formed with the first evaporation coating layer and the second evaporation coating layer by evaporation coating, and introducing a next second substrate to be evaporation coated;
cyclically performing the first position adjustment step, the secondary evaporation coating step, the first feeding step, the second position adjustment step, the repeating evaporation coating step and the second feeding step, so as to form a first evaporation coating layer and a second evaporation coating layer on each of a plurality of first substrates and second substrates to be evaporation coated by the same evaporation device.
